(19) United States
(12) Patent Application Publication
(10) Pub. No.: US 2026/0349345 A1
(43) Pub. Date: Nov. 5, 2026

(54) PHOTOTHERMAL PATTERNING OF POLYMERS

(71) Applicant: The Regents of the University of California, Oakland, CA (US)

(72) Inventors: Adam Moulé, Davis, CA (US); Joaquin Mogollon Santiana, Davis, CA (US); Meghna Jha, Davis, CA (US); Lukas Wegener, Davis, CA (US)

(73) Assignee: The Regents of the University of California, Oakland, CA (US)

(21) Appl. No.: 19/488,039

(22) PCT Filed: Mar. 29, 2024
(86) PCT No.: PCT/US2024/022285

§ 371 Date: Nov. 25, 2025

Related U.S. Application Data
(60) Provisional application No. 63/470,432, filed on Jun. 1, 2023.

(51) Int. Cl. G03F 7/20; B29C 71/02; C08J 5/18; F04B 13/00; G03F 7/00; G03F 7/004; G03F 7/039

(52) U.S. Cl. CPC G03F 7/2041; C08J 5/18; C08J 7/08; F04B 13/00; G03F 7/0048; G03F 7/039; G03F 7/2047; G03F 7/70025; G03F 7/70341; C08J 2365/00; C08J 2379/08

(57) ABSTRACT

A system and method for photothermal patterning is disclosed. The system includes a flow cell. The flow cell includes a cover plate, a substrate having a surface arranged at a distance from the cover plate to form a cavity between the surface and the cover plate, a polymer layer on the surface, an inlet port coupled with the cavity, and an outlet port coupled with the cavity. The system also includes a liquid pump coupled with the inlet port. The liquid pump is configured to flow a solvent through the inlet port and the cavity and out of the outlet port. The system also includes an optical source configured to direct electromagnetic radiation onto a portion of the polymer layer.

### CROSS-REFERENCE TO RELATED APPLICATIONS

This application claims the benefit of and priority to U.S. Provisional Patent Application No. 63/470,432 filed Jun. 1, 2023, the entirety of which is herein incorporated by reference.

### GOVERNMENT RIGHTS

This invention was made with government support under 1636385, and 1804690 awarded by the National Science Foundation. The government has certain rights in the invention.

### TECHNICAL FIELD

The present technology is generally related to the field of photolithography, and in particular, to the field of photothermal patterning of polymers.

### BACKGROUND

Organic polymer films can be useful for various optical, electronic, and/or sensor applications. To support these functions, patterning techniques may be applied to the polymer films. However, various considerations including chemical differences between polymer films and the types of materials that conventional patterning devices are designed to operate on can make it difficult to effectively pattern polymer films to meet scale, performance, and/or quality targets.

### SUMMARY

Disclosed herein are systems and methods for scalable patterning of polymer films using photothermal lithography. The systems can rely on changes in solubility of a polymer in a solvent as a function of temperature to selectively pattern a polymer film. Specifically, electromagnetic radiation can be directed to the polymer film to heat the polymer film to a temperature at which the polymer becomes soluble in the solvent and at particular locations to perform patterning. The system can include a flow cell to sweep dissolved material away in flowing solvent so that the dissolved material does not redeposit on the film or in the pattern. The flow cell, systems, and methods can be compatible with existing cleanroom photolithography equipment to ease adoption.

At least one aspect relates to a system for photothermal patterning. The system can include a flow cell. The flow cell can include a cover plate, a substrate having a surface arranged at a distance from the cover plate to form a cavity between the surface and the cover plate, a polymer layer on the surface, an inlet port coupled with the cavity, an outlet port coupled with the cavity. The system can also include a liquid pump coupled with the inlet port. The liquid pump can be configured to flow a solvent through the inlet port and the cavity and out of the outlet port. The system can also include an optical source configured to direct electromagnetic radiation onto a portion of the polymer layer.

The optical source may be configured to cause local heating in the portion of the polymer layer, thereby causing the portion of the polymer layer to dissolve in the solvent. The liquid pump may be configured to flow the solvent through the cavity to sweep dissolved polymer out of the cavity. The distance between the cover plate and the substrate surface may be a fixed distance between about 0.3 mm and about 0.6 mm.

The flow cell may include a support to which the cover plate and substrate are mounted. The support may include a first chamber where the substrate forms a wall of the first chamber. The system may further include a vacuum pump configured to create a vacuum in the first chamber to secure the substrate to the support. The support may further include a second chamber where the cover plate forms a wall of the second chamber. The vacuum pump may be further configured to create a vacuum in the second chamber to secure the cover plate to the support.

The liquid pump may be at least one of a syringe pump, a metered pump, or a recirculating pump. The substrate may have a circular shape or a rectangular shape. The optical source may include a laser and the system may further include a positioning component to move the optical source laterally with respect to the substrate or to move the substrate laterally with respect to the optical source. The optical source may include a lamp and a shadow mask.

The polymer layer may include poly(3-hexylthiophene) (P3HT); poly(9,9-dioctylfluorene-alt-benzothiadiazole) (F8BT); poly(3-butylthiophene-2,5-diyl) (P3BT); poly[2,5-bis(2-octyldodecyl) pyrrolo[3,4-c]pyrrole-1,4 (2H,5H)-dione-3,6-diyl)-alt-(2,2′; 5′,2″; 5″,2′″-quaterthiophen-5,5′″-diyl) (pDPP-4T); poly {2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl} (pDPP-3T); poly[2,5-(2-octyldodecyl)-3,6-diketopyrrolopyrrole-alt-5,5-(2,5-di(thien-2-yl) thieno[3,2-b]thiophene)](pDPP-2T); or a mixture thereof. The system may further include the solvent disposed in the cavity. The solvent may include a mixture of dichlorobenzene and cyclohexanone.

At least one aspect relates to a method of photothermal patterning a polymer film. The method can include depositing the polymer layer on a surface of a substrate; flowing a solvent over the polymer layer; and while flowing, exposing a portion of the polymer layer to electromagnetic radiation to solubilize the portion of the polymer layer and sweep solubilized organic polymer from the surface in the flowing solvent.

The method may further include securing the substrate to a support by applying a vacuum to a second surface of the substrate. Flowing the solvent may include flowing the solvent at a fixed rate. Flowing the solvent may include flowing the solvent with a pulsed variable rate. Flowing the solvent may include flowing the solvent at a fixed depth of solvent on the polymer layer of about 0.1 mm to about 1 mm.

At least one aspect relates to a flow cell for photothermal patterning. The flow cell can include a support. The flow cell can also include a substrate coupled to the support via mechanical coupling or a pressure differential induced by a vacuum. The flow cell can also include a cover plate coupled to the support via adhesive or a pressure differential induced by a vacuum. The cover plate can be positioned parallel to the substrate at a fixed distance from the substrate to create a cavity therebetween. The fixed distance can be about 0.3 mm to about 0.6 mm. The flow cell can also include a seal sealing the cavity. The flow cell can also include an inlet port configured to direct a solvent into the cavity and an outlet port configured to direct the solvent out of the cavity.

### BRIEF DESCRIPTION OF THE DRAWINGS

FIG. 1 is an illustration of photothermal patterning a polymer film.

FIG. 2 is a schematic diagram of a system for photothermal patterning a polymer film.

FIG. 3 is a cross-sectional schematic diagram of a flow cell for photothermal patterning using vacuum pressure mounting.

FIG. 4 is a top view of the flow cell for photothermal patterning in FIG. 3.

FIG. 5 is a perspective view of the flow cell in FIG. 3 and apparatus for photothermal patterning.

FIG. 6A is a perspective view of an assembled flow cell including a base support and cover plate support for photothermal patterning using mechanical coupling.

FIG. 6B is a top view of the cover plate support in the flow cell in FIG. 6A.

FIG. 6C is a side view of the cover plate support in the flow cell in FIG. 6A.

FIG. 6D is a top view of the base support in the flow cell in FIG. 6A.

FIG. 6E is a side view of the base support in the flow cell in FIG. 6A.

FIG. 7A is a schematic of the optical source of the photothermal patterning system.

FIG. 7B is a zoomed-in perspective of FIG. 7A.

FIG. 8 is a flow diagram illustrating a method of photothermal patterning a polymer film.

FIG. 9 is a schematic of the experimental setup to determine the dissolution temperature of the polymer film in a particular solvent mixture.

FIG. 10 is a chart depicting an upper dissolution temperature vs. good solvent volume fraction for P3HT and N2200 in two different solvent mixtures. The error bars show 95% confidence level and the dashed line are the solvent concentrations.

FIG. 11 depicts multiple charts depicting various line profiles of patterned P3HT with 35% DCB+65% CHN. These line cuts are taken from atomic force microscopy (AFM) images.

FIG. 12A is a schematic of a mathematical model used to calculate an etch depth of a pattern into the polymer film based on an intensity distribution of a laser.

FIG. 12B is a diagram of a Gaussian laser profile vs a position.

FIG. 12C is a 3D plot of FIG. 12B.

FIG. 13A depicts results of a “thru solvent” orientation of the polymer film photomask width vs pattern width at various laser fluences.

FIG. 13B is a schematic of the dissolution and temperature gradients in the polymer film for the “thru solvent” orientation.

FIG. 14A depicts results of a “thru glass” orientation of the polymer film photomask width vs pattern width at various laser fluences.

FIG. 14B is a schematic of the dissolution and temperature gradients in the polymer film for the “thru glass” orientation.

FIG. 15 depicts master curves of data collected from P3HT and PNDI-T2 polymer films.

### DETAILED DESCRIPTION

### Definitions

As used herein and in the appended claims, singular articles such as “a” and “an” and “the” and similar referents in the context of describing the elements are to be construed to cover both the singular and the plural, unless otherwise indicated herein or clearly contradicted by context.

As utilized herein, the terms “approximately,” “about,” “substantially”, and similar terms are intended to include any given ranges or numbers+/−10%. These terms include insubstantial or inconsequential modifications or alterations of the subject matter described and claimed are considered to be within the scope of the disclosure as recited in the appended claims.

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

As will be understood by one skilled in the art, for any and all purposes, all ranges disclosed herein also encompass any and all possible subranges and combinations of subranges thereof. Furthermore, as will be understood by one skilled in the art, a range includes each individual member.

The term “exemplary” as used herein refers to “serving as an example, instance, or illustration,” and not “preferred” or “advantageous over other embodiments.”

Unless defined otherwise, technical and scientific terms used herein have the same meaning as commonly understood by a person of ordinary skill in the art. In particular, this disclosure utilizes techniques in the field of optical spectroscopy and histopathology.

All numerical designations, e.g., pH, temperature, time, concentration, and molecular weight, including ranges, are approximations which are varied (+) or (−) by increments of 1.0 or 0.1, as appropriate or alternatively by a variation of +/−15%, or alternatively 10% or alternatively 5% or alternatively 2%. It is to be understood, although not always explicitly stated, that all numerical designations are preceded by the term “about”. It also is to be understood, although not always explicitly stated, that the reagents described herein are merely exemplary and that equivalents of such are known in the art.

As used herein, the term “comprising” is intended to mean that the devices, systems, compositions and methods include the recited elements, but do not exclude others. “Consisting essentially of” when used to define devices, systems, compositions and methods, shall mean excluding other elements of any essential significance to the combination for the intended use. “Consisting of” shall mean excluding more than trace elements of other elements and substantial method steps for administering the compositions disclosed herein. Embodiments defined by each of these transition terms are within the scope of this disclosure.

### MODES FOR CARRYING OUT THE DISCLOSURE

Disclosed herein are systems and methods for scalable patterning of polymer films using photothermal lithography. These systems and methods use selective exposure of the polymer films with electromagnetic radiation to induce local heating in the polymer films, thereby changing the solubility of the polymer film in the solvent.

Semiconducting organic polymer films can be useful for a multitude of optoelectronic and sensing applications including organic light-emitting diodes (OLEDs), organic electrochemical transistors (OECTs), field-effect transistors (OFETs), photovoltaics (OPVs), optical gratings, microfluidic devices, and biosensors. Many of these devices have laterally patterned sub-μm features. Producing these devices at the commercial scale can mean producing complex electronic circuit architectures over large areas (e.g., 1 cm² to 100 cm²) with high throughput. The inorganic semiconductor industry has widely benefited from the development of optical projection lithography to obtain high throughput, large area, sub-μm patterns for myriad optoelectronic applications. In the future, organic electronic devices are expected to be fabricated on flexible webs or metal foils with varying thicknesses. It is important that any patterning technology is compatible with all substrate geometries.

However, the fundamental chemical differences between organic and inorganic materials have made direct patterning of semiconducting organic polymer films via conventional photolithography techniques difficult. For example, polymer debris formed as a byproduct of the patterning process can redeposit on the polymer film or in the patterned voids during the process of patterning, which can ruin the quality of the patterned polymer film for its use in an electronic device.

In some systems, some aspects of photopatterning semiconducting polymers can be performed using components such as microscopes, lasers, and photomask alignment systems. However, these systems can be impractical to implement, due to factors such as significant size, weight, and power (SWAP), and/or cumbersome form factors.

Systems and methods in accordance with the present disclosure can enable scalable pattering of polymer films, using photothermal lithography, by substantially hindering or preventing polymer debris such as dissolved polymer formed as a byproduct of the patterning process from redepositing on the polymer film or in the patterned voids. Redeposition of polymer debris can be hindered or prevented by flowing a solvent over the surface of the polymer film during the patterning process, where the flowing solvent can sweep away dissolved polymer and other debris from the surface of the polymer film. In this way, the systems and methods in accordance with the present disclosure can produce high-quality patterned polymer films with increased efficiency, higher throughput, and higher scalability. The systems and methods in accordance with the present disclosure can be implemented using systems such as cleanroom photolithography equipment (e.g., without relying on cumbersome combinations of disparate components). Various such systems and methods can be implemented with more precise patterning, e.g., by facilitating control of the equipment based on a model of the response of the polymer film to controllable parameters of the patterning process.

A polymer film can be coated onto a substrate and then immersed in a solvent that does not dissolve the polymer film at an operating temperature (T) and dissolves the polymer film at a threshold elevated temperature (T+ΔT). The laser can be focused onto the surface of the immersed polymer film, causing light to be absorbed by the polymer film. The absorbed light can create excitons in the polymer film, which relax to the ground state through non-emissive processes and locally heat the polymer film in the portion of the polymer film irradiated. The locally heated polymer film portion can reach the threshold elevated temperature (T+ΔT) and the polymer in that portion can dissolve into the solvent phase, leaving a void in the film. The solvent can flow across the polymer film during patterning to sweep away the dissolved polymer, thereby preventing dissolved polymer from redepositing on the polymer film or in the new film voids.

The normal operating temperature (T) of the solvent in the photothermal patterning system may have a range. The normal operating T of the solvent in the photothermal patterning system may be about 1 °C to about 70 °C. The normal operating T of the solvent in the photothermal patterning system may be about 4 °C to about 40 °C. The threshold elevated temperature (T+ΔT) at which the polymer film spontaneously dissolves in the solvent may be such that ΔT is about 10 °C to about 100 °C. In some implementations, it can be useful for the operating temperature range to be relatively narrow (e.g., in a narrower range than those discussed above), such as to allow for more efficient and/or reproducible operation.

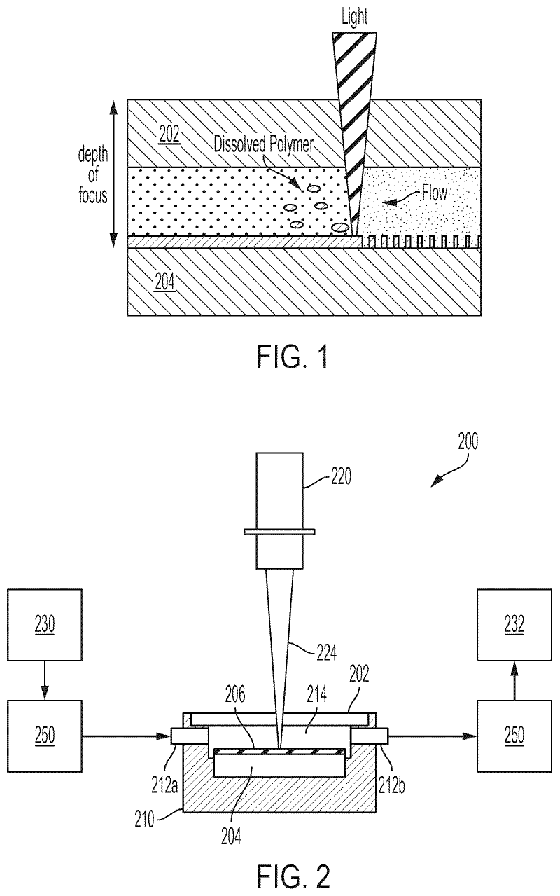

FIG. 1 is a cross-sectional illustration of the process of photothermally patterning a polymer film immersed in flowing solvent. The polymer film can be disposed on the surface of a substrate. The solvent can be flowed across the polymer film. A cover plate can be disposed parallel to the substrate to create a cavity between the cover plate and the substrate. A light can be directed through the cover plate and through the solvent and focused onto a portion of the surface of the polymer film immersed in the flowing liquid solvent. The depth of focus is indicated on the side of the figure. The light can locally heat the portion of polymer film irradiated, increasing the polymer solubility, and causing the polymer in that portion to dissolve into the solvent. The dissolved material can be swept away from the polymer film and substrate in the flowing solvent. To develop a pattern, either the substrate can be moved with respect to the light, or the light can be moved with respect to the substrate. At locations where the light irradiates the polymer film surface, the polymer can be dissolved, leaving behind a laterally patterned polymer film on the substrate.

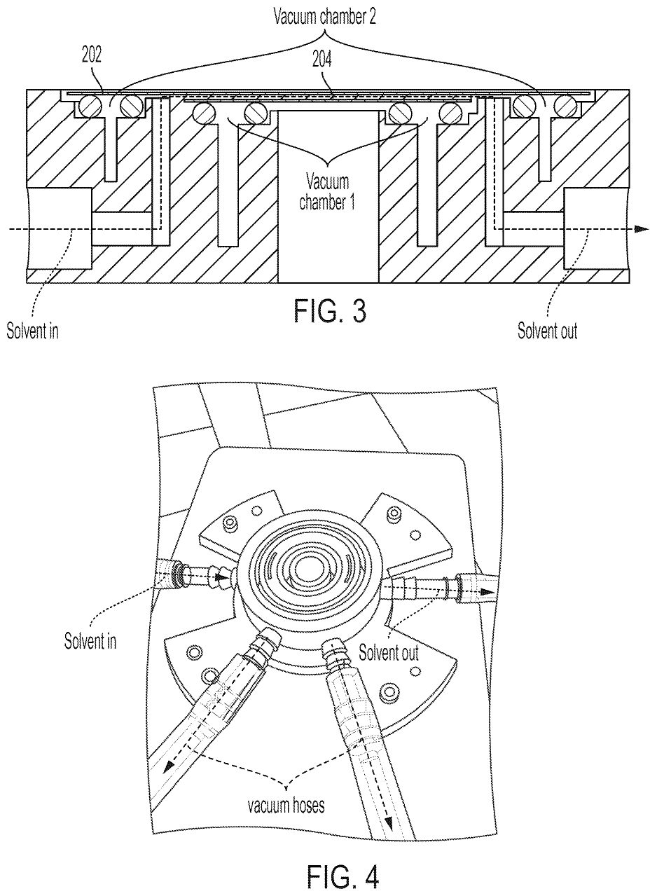

FIG. 2 is a schematic cross-sectional diagram of a system 200 for photothermally patterning a polymer film. The system 200 can include a flow cell 210. A substrate 204 with a polymer film 206 disposed on a surface of the substrate 204 can be mounted in the flow cell 210. A liquid solvent can be directed through the flow cell 210 and over the surface of the polymer film 206 during photothermal patterning to sweep away polymer debris. A cover plate 202 can also be mounted in the flow cell 210 at a fixed distance from the substrate 204 to create a cavity 214 disposed between the cover plate 202 and the substrate 204. The liquid solvent can flow through the cavity 214. The liquid solvent can be replaced with new solvent. The liquid solvent can be filtered and re-circulated. The flow cell 210 can also include an inlet port 212a and an outlet port 212b that are fluidically coupled to the cavity 214.

The system 200 can include a solvent source 230 and a solvent collector 232. The solvent source 230 and the solvent collector 232 can be fluidically coupled to the inlet port 212a and the outlet port 212b to provide a flow of solvent to the flow cell 210. In some embodiments, solvent that flows through the flow cell 210 may be collected in the solvent collector 232, cleaned, and then recirculated through the flow cell 210. In other embodiments, solvent is not recirculated and is instead directed to waste.

The system 200 can include at least one liquid pump 250. The liquid pump 250 can be connected to the solvent source 230 and/or the solvent collector 232. As an example, the liquid pump 250 may be a syringe pump. The liquid pump 250 may be a recirculating pump. The liquid pump 250 may be a metered pump, such as a flow rate metered pump. The liquid pump 250 is configured to pump the solvent from the solvent source 230, through the inlet port 212a, through the cavity 214 and over the surface of the polymer film 206, out of the outlet port 212b, and to the solvent collector 232. The liquid pump 250 can be operated to provide a continuous, steady flow rate and/or can be operated to provide a pulsed variable flow rate of solvent through the flow cell 210. The flow rate of the solvent through the flow cell 210 may be adjusted depending on the viscosities of the solvent and polymer.

The system 200 can include an optical component 220, which directs electromagnetic radiation 224 to the polymer film. The optical component 220 can include an electromagnetic radiation source. The optical component 220 may also include mirrors or lenses to facilitate light focusing on the polymer layer. In any embodiment, the electromagnetic radiation may be ultraviolet, visible, or infrared light. As an example, the electromagnetic radiation source may be a laser or a lamp. The optical component 220 may include or be coupled with a mask, such as a shadow mask, to form the desired pattern. In some embodiments, the optical component may also include a positioning component to direct the electromagnetic radiation 224 laterally across a surface of the substrate 204. The positioning component can be mirrors using a micro-electromechanical system (MEMS) array. In some embodiments, the optical component may be stationary and the substrate 204 may be on a lateral translation stage so that the electromagnetic radiation 224 moves laterally across the substrate 204.

The polymer layer material may be any polymer that strongly absorbs light so that it can be patterned. The polymer layer material may be a polymer that absorbs light strongly enough so that the polymer layer locally increases in temperature above the polymer dissolution threshold temperature. Furthermore, the polymer layer material may have a molecular weight that is high enough to entangle the polymer. In some embodiments, the polymer layer material may be a polymer that is otherwise transparent and insulating but has dye molecules or other materials to make it colored (e.g., be at least partially reflective to visible light).

The polymer layer material may include a conjugated polymer. For example, the polymer layer material may include a conjugated polymer typically used in organic electronics. Many conjugated polymers used in organic electronics have similar solubilities, which means that the same or similar solvent may be advantageously used to photothermally pattern different polymer layers. The polymer layer material may include a conjugated polymer that absorbs laser light.

Examples of the polymer layer material include poly(3-hexylthiophene) (P3HT); poly(9,9-dioctylfluorene-alt-benzothiadiazole) (F8BT); poly(3-butylthiophene-2,5-diyl) (P3BT); poly[2,5-bis(2-octyldodecyl) pyrrolo[3,4-c]pyrrole-1,4 (2H,5H)-dione-3,6-diyl)-alt-(2,2′; 5′,2″; 5″,2′″-quaterthiophen-5,5′″-diyl) (pDPP-4T); poly {2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl} (pDPP-3T); poly[2,5-(2-octyldodecyl)-3,6-diketopyrrolopyrrole-alt-5,5-(2,5-di(thien-2-yl) thieno[3,2-b]thiophene)] (pDPP-2T); or a mixture thereof.

The solvent used in the photothermal patterning system may be any appropriate solvent that is semi-poor with respect to the polymer layer material. A good solvent causes chain expansion, making the polymer more likely to separate and dissolve. A poor solvent causes polymer chains to collapse. A semi-poor solvent may cause temperature-dependent polymer dissolution. That is, the solubility of the polymer layer material in the semi-poor solvent may change with respect to temperature. The solvent may be a pure solvent or a mixture of solvents. The solvent may be polar or nonpolar.

The solvent used in the photothermal patterning system may be a mixture of a good solvent and a poor solvent. The ratio of good solvent to poor solvent may influence the dissolution temperature and rate of the polymer film. Examples of the solvent include a mixture of dichlorobenzene (acting as the good solvent) and cyclohexanone (acting as the poor solvent).

The solvent used in the photothermal patterning system may be a miscible solvent. The solvent may be a mixture that can dissolve the polymer film at an elevated temperature. The solvent may have a boiling point that is higher than the polymer dissolution temperature (DT). Examples of the solvent include chlorobenzene, methyl-THF, acetonitrile, and ortho-xylene. Further examples of the solvent include acids, water, bases, organics, and fluorinated solvents. The solvent can be a carrier of heat. The solvent can be a medium to remove the polymer.

The temperature of the flow cell 210 may be controlled using a temperature-control component, such as a hot plate thermally coupled to the flow cell 210. The temperature of the flow cell 210 and solvent may further be controlled by heating or cooling the solvent in the solvent source 230 and/or the solvent collector 232. The temperature control may facilitate the desired polymer solubility traits described above.

The shape of the flow cell 210 and the substrate 204 may change the way solvent flows through the flow cell 210. For example, the flow cell 210 and/or the substrate 204 may have a circular shape. A circularly shaped flow cell 210 can have a complicated flow pattern including turbulent flow. As another example, the flow cell 210 and/or the substrate 204 may have a square or rectangular shape. Square or rectangular shapes may provide a uniform and/or laminar flow pattern.

The substrate 204 and the cover plate 202 may be coupled to the flow cell 210 via mechanical coupling, pressure differential, adhesive bonding, or a combination thereof. Illustrative examples of mechanical couplings include bolt fasteners, clamps, and magnetic fasteners. A pressure differential may be created in the flow cell 210 using a vacuum pump fluidically coupled to the flow cell 210. The vacuum pump can create a vacuum in one or more chambers within the flow cell 210 to secure the substrate 204 and/or the cover plate 202 to the flow cell 210 via the pressure differential. Alternatively or additionally, the substrate 204 and/or cover plate 202 may be secured to the flow cell 210 via chemically-resistant adhesive. The flow cell 210 may be made of metal or polymer that is resistant to the solvent used during operation.

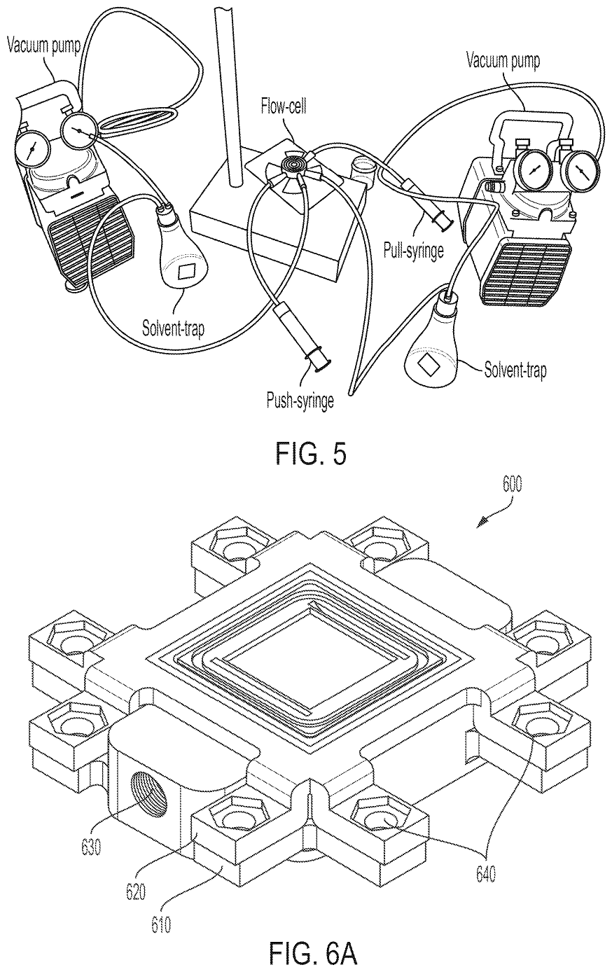

FIG. 3 is a cross-sectional schematic of a flow cell 300 for photothermal patterning. The flow cell 300 can use flowing solvent to remove the dissolved polymer and substantially hinder or prevent the dissolved polymer from redepositing on the polymer film or in the patterned voids during the process of patterning. This is useful because dissolved polymer that redeposits on the surface of the polymer film or in the patterned voids can ruin the quality of the patterned polymer film for its use in an electronic device.

The polymer film can be disposed on a surface of the substrate 204 shown mounted in the flow cell 300 in FIG. 3. The cover plate 202 can also be mounted in the flow cell 300 and disposed parallel to the substrate 204 to create a cavity between the cover plate 202 and the substrate 204. The distance between the cover plate 202 and the substrate 204 may be a fixed distance defined by the shape of the flow cell's 300 support structure. As an example, the fixed distance may be between about 0.3 mm and about 0.6 mm. The cavity between the cover plate 202 and the substrate 204 may be sealed with one or more O-rings to contain the solvent. The cover plate 202 and cavity may facilitate a thin, well-defined depth and volume of solvent above the polymer film surface (e.g., about 0.1 mm to about 1 mm of solvent; about 0.3 mm to about 0.6 mm). Depth and volume of solvent can be other values depending on various factors described herein. The flow cell 300 can be a closed system that prevents dust and other atmospheric contaminants interfering with the patterning process. The cover plate 202 may be made of a glass or polymer material that is transparent or substantially transparent to the wavelengths of electromagnetic radiation used for patterning.

The flow cell 300 in FIG. 3 can include a solvent inlet port 301a and a solvent outlet port 301b to provide flowing solvent across the polymer film. Solvent can flow into the flow cell 300 through the inlet port 301a, across the polymer film surface, and out of the outlet port 301b.

The substrate 204 can be removably mounted on a support structure within the flow cell 300 in FIG. 3. The support structure can include a first chamber 302, where part of the substrate 204 forms a wall of the first chamber 302. A vacuum pump can be coupled to the support structure to create a vacuum in the first chamber 302 in order to secure the support structure in the flow cell 300. The cover plate 202 can be mounted on the support structure within the flow cell 300 so that the cover plate 202 is disposed parallel to the substrate 204 to create a cavity between the cover plate 202 and the substrate 204. The support structure can include a second chamber 304, where part of the cover plate 202 forms a wall of the second chamber 304. The same vacuum pump or a second vacuum pump may be coupled to the support structure to create a vacuum in the second chamber 304 in order to secure the cover plate 202 to the flow cell 300. The substrate 204 and the cover plate 202 can be sealed against the first chamber 302 and the second chamber 304, respectively, with one or more O-ring seals.

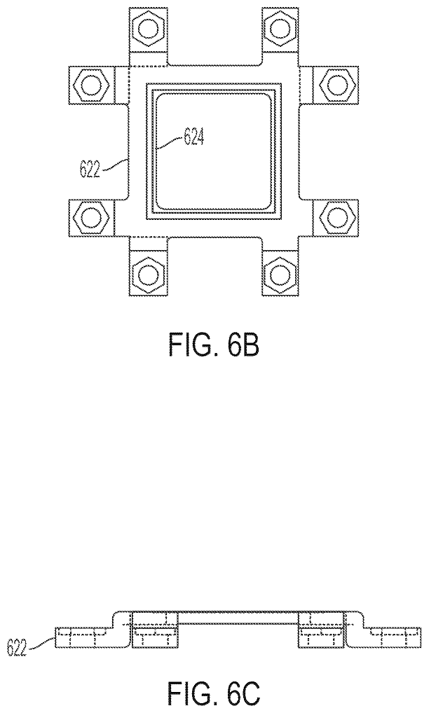

FIG. 4 is a top view of the flow cell 300 shown in FIG. 3 for photothermal patterning. The flow cell 300 can include the solvent inlet port 301a and the solvent outlet port 301b to provide a flow of solvent across the polymer film surface during operation. The flow cell 300 can also include two vacuum hoses 402 that are coupled to the same or different vacuum pumps. Each vacuum hose 402 can be connected to a different chamber, e.g., 302 and 304, in the flow cell's 300 support structure to create a vacuum in respective chambers to secure the cover plate 202 and substrate 204 in place.

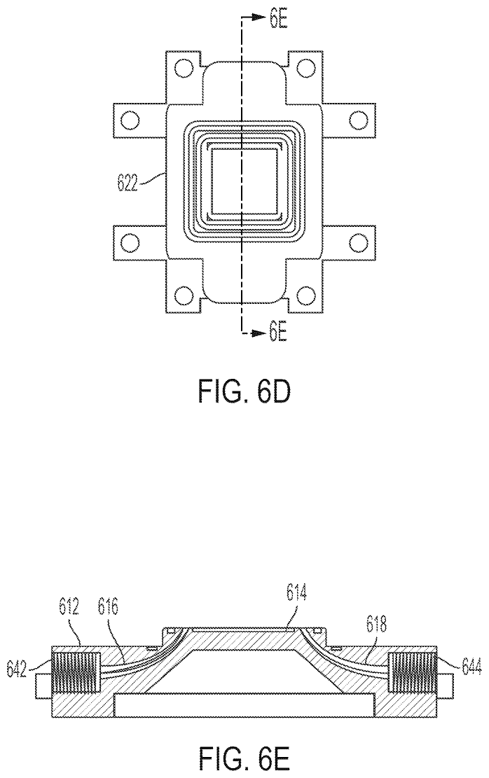

FIG. 5 is a perspective view of the flow cell 300 and related components for photothermal patterning. The components can include two vacuum pumps 502a and 502b, two solvent traps 506a and 506b, two push-pull syringe pumps 508a and 508b, and the flow cell 300 itself. The vacuum pumps 502a and 502b can be used to create a vacuum in the flow cell 300 to hold the substrate 204 and cover plate 202 in place. Two solvent traps 506a and 506b can be fluidically disposed between the vacuum pumps 502a and 502b and the flow cell 300 to collect solvent that may incidentally leak into the vacuum chamber. The push-pull syringe pumps 508a and 508b can insert and remove solvent from the flow cell 300. In some embodiments, the push-pull syringe pumps 508a and 508b may be automated and the flow rate of the solvent in the flow cell 300 can be set by an automatic syringe pump.

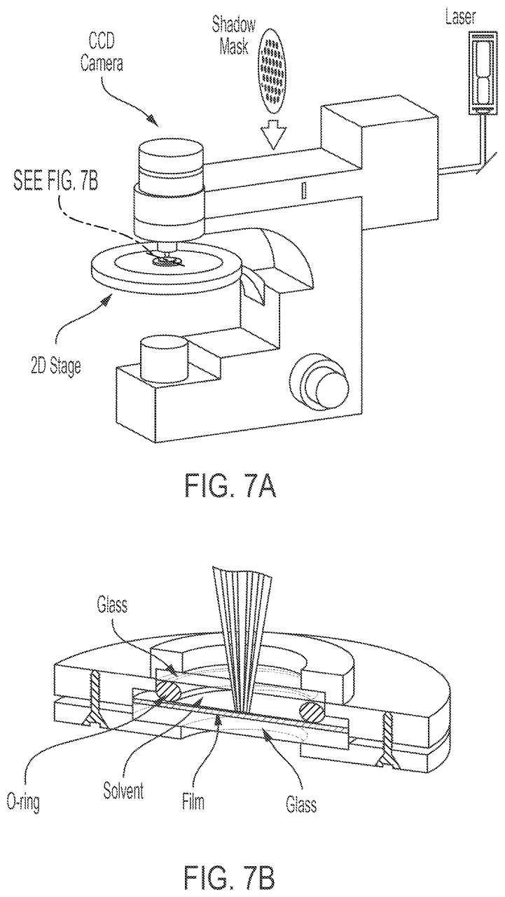

FIG. 6A is a perspective view of an assembled flow cell 600 for photothermal patterning that uses mechanical coupling to mount the substrate and cover plate. The flow cell 600 can be made of metal, in some implementations. A metal flow cell 600 can provide enhanced durability. The flow cell 600 includes a base support 610 and cover plate support 620 that come together to form the assembled flow cell 600. The flow cell 600 includes a conical-shaped inlet 630 and a conical-shaped outlet to direct solvent into and out of the cavity between the cover plate and substrate. The flow cell 600 includes eight connection points 640 at which mechanical couplings are used to mount the base support 610 to cover plate support 620, with the substrate and cover plate mounted therebetween. Illustrative examples of mechanical couplings that may be used in the flow cell 600 include, but are not limited to, bolt fasteners, clamps, and magnetic fasteners. The flow cell 600 can have various geometries. For example, the flow cell 300 can have a generally circular shape while the flow cell 600 can have a generally rectangular shape.

FIG. 6B is a top view of the cover plate support 620 in the flow cell 600 in FIG. 6A. FIG. 6C is a side view of the cover plate support 620 in the flow cell 600 in FIG. 6A. The cover plate support 620 includes a groove 624 in which the cover plate may be mounted. The height of the cover plate support 620 shown in the side view in FIG. 6C determines the spacing distance between the cover plate and the substrate. Once assembled, the spacing distance may be about 0.1 mm to about 0.5 mm. For example, the spacing distance may be about 0.15 mm to about 0.25 mm. In an embodiment, the spacing distance is about 0.17 mm to about 0.22 mm. The flow cell 600 may have more precise spacing than the flow cell 300 in FIG. 3 because of the use of mechanical fasteners instead of vacuum to mount the substrate and cover plate.

FIG. 6D is a top view of the base support 610 in the flow cell 600 in FIG. 6A. FIG. 6E is a side view of the base support 610 in the flow cell 600 in FIG. 6A. The base support 610 includes a depression 614 in which the substrate may be mounted. Inlet 642 and outlet 644 provide a flow of solvent over the surface of the substrate during operation. Solvent is directed through the base support 610 through channels 616 and 618, which may be conical-shaped to provide laminar flow of solvent. In some embodiments, an O-ring may be used to seal the base support 610 to the cover plate support 620.

As shown in the side view of the flow cell 600 in FIG. 6E, the flow cell 600, such as the base support 610, can include components coupled based on pressure between components. For example, the base support 610 can have relatively few components, e.g., three members; this can allow for reduced likelihood of leaks between interfaces of the components.

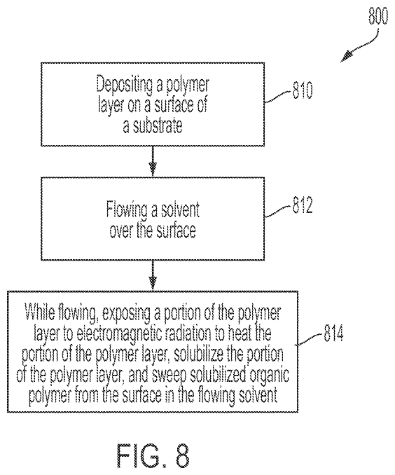

FIGS. 7A and 7B is a schematic of the optical source of the photothermal patterning system. The optical source may include a 2D stage 702, a camera 704, a shadow mask 706, and a laser 708. The 2D stage 702 can hold, mount, house the polymer film 716 to be patterned. The camera 704 can be a charged coupled device (CCD) camera and can detect light. The shadow mask 706 can provide, control, manipulate light to pattern the polymer film 716. The laser 708 can be a light source for the photothermal patterning system. The optical source may include a microscope that provides focused light onto a polymer film 716. The optical source may be a custom component configured for photothermal patterning or the optical source may be a conventional optical component used in photolithography.

The optical part of the system may be a conventional photolithography equipment for ease of integration of photothermal patterning into existing lithography systems. Conventional photolithography optics are intended to focus light onto the outside surface of a substrate. The light is focused onto the outer substrate/air or substrate/vacuum interface. In photothermal patterning, the polymer film 716 is not located at the outer substrate/air interface. Instead, the polymer film 716 is located on a substrate surface in the flow cell cavity immersed in solvent. In photothermal patterning, the light passes through both a cover plate 714 and also through a solvent layer 712 before reaching the polymer film 716 as depicted in FIG. 7B. This distance through the cover plate 714 and solvent 712 defines the depth of focus. The thickness of the cover plate 714 and depth of the solvent layer 712 above the polymer film 716 may be adjusted relative to the focusing range of the conventional photolithography optics. For example, conventional photolithography optics can typically be focused in a range of about 0.5 mm, so the total thickness of the cover plate 714 and solvent layer 712 may be set at 0.5 mm so that the light from the conventional optics may be focused onto the polymer film 716. The optical part of the system may also include a substrate 718 for the polymer film 716 to attach to and a sealing member 710 to seal the cover plate 714. The sealing member 710 can be an O-ring.

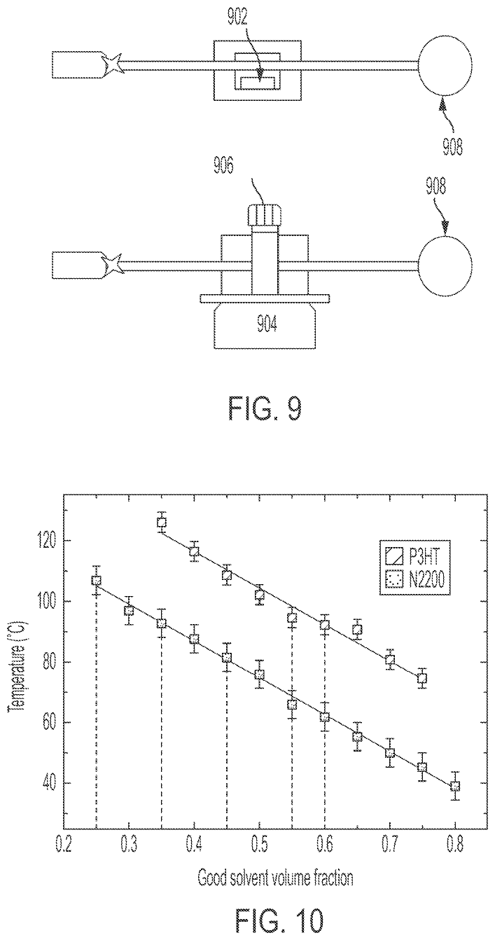

FIG. 8 is a flow chart illustrating a method 800 of photothermally patterning a polymer film. Various aspects of the method 800 can be implemented using automatic processes, such as by using an electronic controller to control operation of one or more components of the system 200 according to one or more programmatic instructions and/or inputs to a user interface or other control interface of the controller. The method 800 can be implemented to perform any of a variety of batch and/or continuous processes of patterning polymer films.

At 810, a polymer layer can be deposited on a surface of a substrate. The polymer layer can have a thickness. The thickness of the polymer layer can be in a range of 20 nm to 1000 nm. The thickness of the polymer layer may be the thickness of a single molecular layer. The polymer layer can be deposited via liquid-phase coating methods (e.g., spin coating or spray coating) or gas-phase coating methods (e.g., chemical vapor deposition (CVD) or molecular layer deposition (MLD).

At 812, a solvent can be flowed over the polymer layer. Initiation and operation of the solvent flow may be responsive to initiation and operation of the optics components in the system exposing a portion of the polymer film to radiation. The solvent can be flowed in response to the system receiving an instruction to operate the liquid pump. The solvent can be flowed in response to exposure of the polymer film to electromagnetic radiation. The optics components can be operated responsive to initiation of solvent flow by the liquid pump. The optics components may be initiated at a predetermined time after initiating solvent flow. Solvent flow can be continuous or pulsed.

At 814, while flowing the solvent over the polymer layer, a portion of the polymer layer can be exposed to electromagnetic radiation to heat the portion of the polymer layer. Flowing the solvent can include flowing the solvent at a fixed depth of solvent on the polymer layer. The fixed depth can be about 0.1 mm to 1 mm. The fixed depth can be other values depending on a flow cell configuration and desired pattern. Heating the portion of polymer layer solubilizes the portion of the polymer layer in the solvent. Once solubilized, the solubilized polymer material is swept away in the flowing solvent to prevent the solubilized material from redepositing on the polymer layer or newly formed patterning vacancies.

### Photothermal Patterning Operation and Control

Referring further to FIGS. 1-8, the systems and methods of the present disclosure can be implemented using various devices, such as photolithography equipment in a cleanroom, to pattern polymer films. Such devices can be operated, for example, according to a model that relates parameters of device operation to one or more characteristics of the patterned polymer films, such as pattern size and resolution.

In some implementations, one or more aspects of the present disclosure can be implemented using the cleanroom equipment such as the PRIMO manufactured by Alveole U.S.A. of Fairfax, Virginia, such as to enable micro-patterning, hydrogel polymerization and microfabrication. This can enable photothermal patterning technique on a p-type and an n-type polymer at various solvent concentrations and laser fluence. The results of enabling photothermal patterning techniques with various parameters can result in a quasi-steady state model to investigate a dissolution behavior of polymer films in solvent mixtures induced by a Gaussian laser beam's heating effect to analyze an effect of depth of focus, solvent concentrations, and laser fluences that can affect pattern size and resolution.

### EXAMPLES

Process patterns such as solvent concentration, fluence of the laser, molecular weight, poly dispersity index of the polymer film, and dwell time can affect the pattern shape and resolution. These process patterns can be controlled by controlling temperature gradients in the polymer film. The specific polymer films used in the compatibility testing experiment was poly(3-hexylthiophene) (P3HT) and poly[N,N′-bis(2-octyldodecyl)-naphthalene-1,4,5,8-bis(dicarboximide)-2,6-diyl]-alt-5,5′-(2,2′-bithiophene) (PNDI-T2). P3HT is a p-type homopolymer that is highly crystalline, orients perpendicular to the substrate, and absorbs poorly at 375 nm laser fluence. PNDI-T2 is an n-type alternating co-polymer with low crystallinity, orients parallel to the substrate, and absorbs strongly at 375 nm. PNDI-T2 can herein be referred to as N2200.

1,2-dichlorobenzene (DCB) was used as the good solvent for P3HT and cyclohexanone (CHN) was used as the poor solvent for P3HT. p-xylene (XLN) was used as the good solvent for PNDI-T2 and CHN was used as the poor solvent for PNDI-T2. The good solvent will fully dissolve the polymer film while a poor solvent will not dissolve the polymer at all at room temperature.

In overview, P3HT and PNDI-T2 can be patterned using photothermal lithography, e.g., on cleanroom photolithography equipment. A quasi-steady state model was developed to investigate the dissolution behavior of polymer films in solvent mixtures induced by a Gaussian laser beam's heating effect. Through the experiment, the depth and width of the patterns obtained were determined and identified an influence of solubility kinetics on heat transfer dynamics. The regime in which the heat transfer effects dominate was identified and enabled a modification of a shape of the patterns obtained. The experiment significantly contributes to development of a cost-effective and rapid patterning technology for semiconducting polymers and opens up new possibilities for industrial applications in the field of electronic devices.

Process parameters used during photothermal lithography can affect a shape and resolution of the pattern. Process parameters can include solvent quality, e.g., specific interactions with good and poor solvents and their ratio. Process parameters can include polymer molecular weight (Mw), polymer polydispersity index (PDI), laser fluence (E_{P}), laser intensity, and laser dwell time. Process parameters can manipulate a temperature gradient in the polymer film. Process parameters can manipulate locations at which a dissolution temperature (DT) is reached. Process parameters can dictate a resulting pattern and dissolution rate. PDI for a semiconducting polymer film can be greater than 1. There can be a range of temperatures over which the polymer film dissolves in a solvent. DTₛₜₐᵣₜ can be a minimum temperature at which the polymer film starts to dissolve into the solvent mixture. DT_{end} may be a maximum temperature at which the polymer film dissolves into the solvent mixture. DT start may be low enough that it can be achieved in an efficient manner by thermal heating from the laser. DTₛₜₐᵣₜ may be higher enough so that the polymer film does not dissolve into the solvent at room temperature even after hours of the polymer film soaking in the solvent.

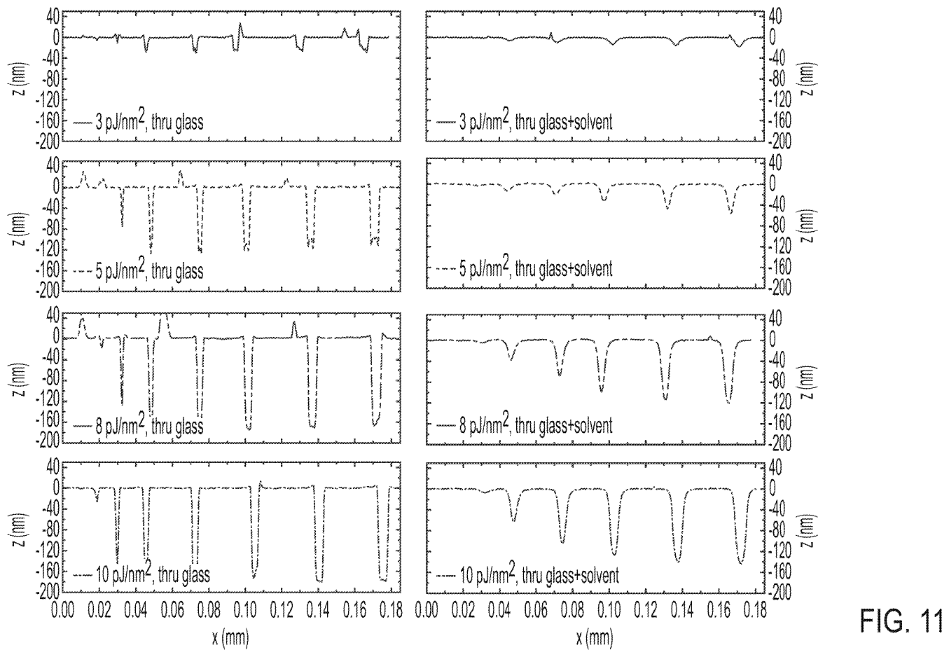

Referring to FIG. 9, FIG. 9 depicts an experimental setup to demonstrate the compatibility of commercial equipment with the systems and methods of the present disclosure. The experiment polymer film 902 and the experiment solvent mixture were placed in a cuvette on a hotplate 904. The experiment polymer film 902 can be coated on a substrate and immersed in the cuvette. A 405 nm 20 mW laser was used to probe a transmittance (e.g., a fraction of the laser that is transmitted) through the solvent as the experiment polymer film 902 begins to dissolve. A 3 °C/min temperature ramp up from room temperature was used to slowly increase temperature of the experimental polymer film 902 and the experiment solvent mixture.

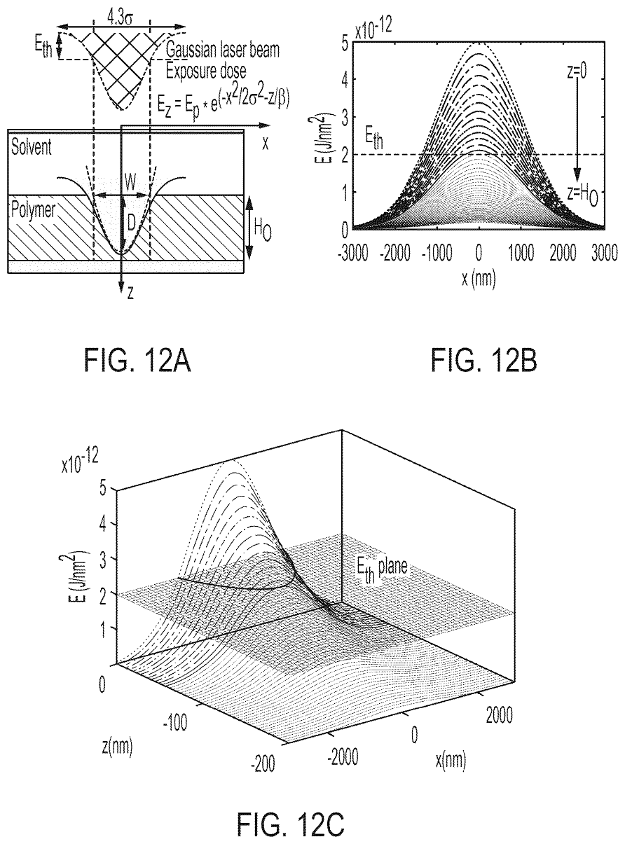

Transmittance begins to decrease as the experiment polymer film 902 dissolves in the experiment solvent mixture 902. This can change a color of a contents of the cuvette. A complete dissolution of the experiment polymer film 902 in the experiment solvent mixture represents a dissolution temperature. The dissolution temperature can be recorded by a thermocouple 906. The experimental setup in FIG. 9 can also include a photodetector 908 can be a sensor, detector and can measure properties of the laser. FIG. 10 depicts the dissolution temperature of P3HT in a mixture of DCB and CHN as well as PNDI-T2 in a mixture of XLN and CHN. Dashed lines depicted in FIG. 10 indicate tested solvent concentration ratios with a significant difference in dissolution temperature.

FIG. 10 depicts a chart of temperature (°C) versus a volume fraction of the good solvent. Selection of a solvent concentration for patterning can be based on the DTₛₜₐᵣₜ. DTₛₜₐᵣₜ for PNDI-T2 in XLN+CHN is higher than that of P3HT in DCB+CHN. To pattern PNDI-T2 and P3HT at the same DT, a solvent ratio must be changed. Dashed lines depicted in FIG. 10 are solvent concentrations chosen for experimentation. DTₛₜₐᵣₜ can be about 30 °C lower than DT_{end} since semiconducting polymers have a PDI of 2 to 4. A low DT start can result in a systematic reduction of a thickness of the polymer film by dissolution of shorter polymer chains in the polymer film.

The experiment polymer film 902 was enclosed in a solvent cell depicted in FIG. 9 with a 300 μm (<200 μl total solvent) layer of the experiment solvent mixture for a patterning experiment.

The photomask image was projected on a surface of the experiment polymer film 902 and exposed to a 375 nm laser embedded in the commercial equipment. An image of the photomask was projected on the surface of the experiment polymer film 902 prior to patterning. P3HT and PNDI-T2 in solid state have significant absorbance at 375 nm based on the UV-Vis-NIR spectra. A 20× objective lens and a projection area of approximately 0.17 mm² was used in this experiment. P3HT was tested with varying solvent concentrations, laser fluences, and solvent cell orientations. P3HT and PNDI-T2 displayed similar results. The three solvent concentrations of DCB to CHN were 25%, 35%, and 45% (e.g., 25% DCB and 75% CHN). The four laser fluences used were 3, 5, 8, and 10 pJ/nm². A solvent cell assembly included two glass pieces that can enclose and lock the solvent in place. One glass piece is a 0.1 mm coverslip. Another glass piece is a 1 mm microscope slide or ITO glass. The experiment polymer film 902 was coated on one of the two glass pieces such that the experiment polymer film 902 was always in contact with the experiment solvent mixture 902. The laser had to travel through different materials and distances to reach the experiment polymer film 902. An orientation in which the laser had to travel through glass alone to reach the polymer can herein be referred to as a “thru glass” orientation. Where the laser travelled through the glass and the solvent to reach the experiment polymer film 902 can herein be referred to as “thru solvent” orientation.

The “thru solvent” orientation enables a use of standard thickness substrate. However, there are more optical interfaces and a larger working distance between the laser source and the polymer film for the “thru solvent” orientation compared to the “thru glass”. The “thru glass” orientation uses the coverslip for the substrate but reduces a focal distance of the laser and removes reflectance off the interfaces. Furthermore, the laser heats the glass and polymer film interface in the “thru glass” orientation while in the “thru solvent” orientation, the laser heats the solvent and polymer film interface.

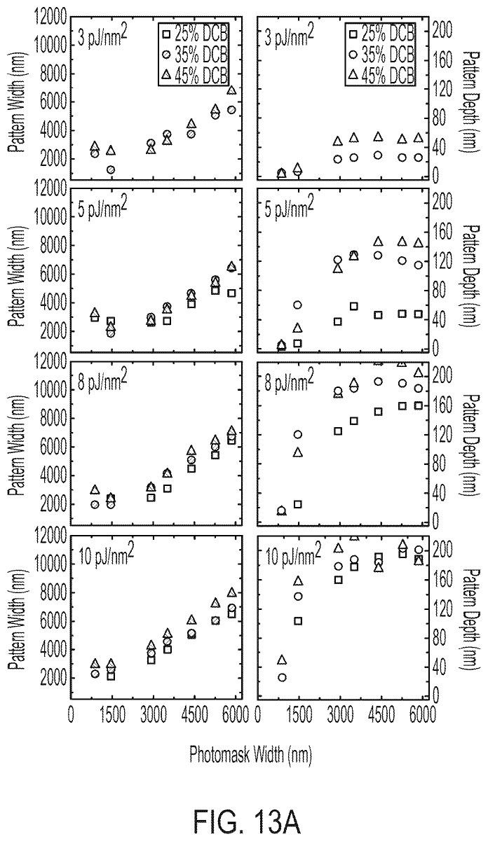

FIG. 11 depicts atomic force microscopy (AFM) images and line profiles (e.g. illustration of vertical cross section of a patterned polymer film) of patterns obtained for P3HT with a solvent mixture of 35% DCB and 65% CHN for both orientations and all 4 laser fluences, and 7 different exposure widths tested. FIG. 11 shows that there are discernible differences in the line profiles obtained for the two orientations and four fluences. Increasing the laser fluences resulted in deeper patterns and the “thru solvent” orientation resulted in wider patterns on the experiment polymer film 902. There was also an increased polymer redeposits for the “thru glass” orientation which resulted in positive features (e.g., added dimension to the experiment polymer film 902). This could be due to the orientation of the solvent cell and effects of gravity.

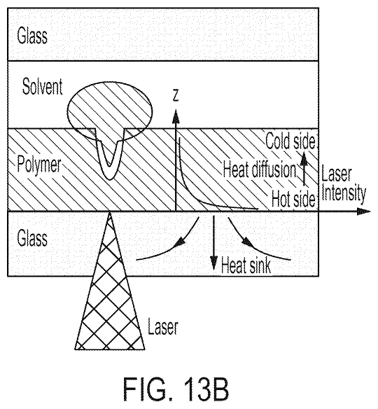

FIGS. 12A-C depict Gaussian laser beam profiles from the “thru solvent” orientation. FIG. 12A depicts a schematic overview of the patterning process specifically for the “thru solvent” orientation of the solvent cell.

To understand dissolution of the experiment polymer film 902 in the experiment solvent mixture, a threshold energy (Eₜₕ) was associated with the experiment polymer film 902 and experiment solvent mixture. Eₜₕ can be the cumulative optical power (J/nm²) needed to reach DT start. Eₜₕ can depend on the choice of solvent mixture since the polymer film will dissolve at a lower temperature in a better solvent which corresponds to a lower Eₜₕ. For example, an experimental setup of 35% DCB and 65% CHN and P3HT can have a unique Eₜₕ associated with the setup, below which the P3HT will not dissolve in 35% DCB and 65% CHN. For a quasi-steady state system (e.g., a system changing slowly enough to be considered constant), the dissolution can occur over a timescale of seconds to minutes. A rate of dissolution can be dependent on the quality of solvent, a polymer, heat inputted in the system, and the Eₜₕ (i.e., parameter that describes the dissolution process).

This system can be modelled by a gaussian laser beam projected on a top surface of the experiment polymer film 902 that is exposed to the experiment solvent mixture such that no dissolution occurs at room temperature as seen in FIG. 12A. This can result in absorption of photons which can lead to heating of the experiment polymer film 902. Once a local temperature (e.g., temperature of the experiment polymer film 902 and the experiment solvent mixture) passes the dissolution temperature, the experiment polymer film 902 starts to dissolve in the experiment solvent mixture. The polymer film starts to dissolve into the solvent mixture when the local temperature of the polymer film exceeds DT start. The gaussian laser beam distribution with a width can be expressed as:

$$E ( x , z ) = {E}_{p} exp ( - \frac{{x}^{2}}{{σ}^{2}} ) exp ( - \frac{z}{β} )$$

where Eₚ is the peak exposure dose at x=z=0. This gaussian distribution function is described in the x-direction and exponentially decreasing in the z-direction with a decay constant β.

Using a model for exposure profiles for a photoresist exposed to a gaussian laser function with an exponential decay, y, known as the contrast, is used to understand the difference between the exposed and the unexposed region on the polymer. A higher y points towards a more observable difference between the exposed and the unexposed area. The contrast curve for a positive photoresist has been used as a control for this system of photolithography due to similarities in the mechanism of pattern formation where y can be defined as:

$$γ = \frac{\frac{z}{{H}_{o}}}{log \frac{E ( z )}{{E}_{th}}}$$

Rearranging the aforementioned equations with spatial parameters x and z:

$$z = \frac{{γH}_{o}}{1 + \frac{γ {H}_{o}}{β}} [ ln \frac{{E}_{p}}{{E}_{th}} - \frac{{x}^{2}}{{σ}^{2}} ] = A - B {x}^{2}$$

$$A = \frac{{γH}_{o}}{1 + \frac{γ {H}_{o}}{β}} ln \frac{{E}_{p}}{{E}_{th}} , B = \frac{{γH}_{o}}{1 + \frac{γ {H}_{o}}{β}} [ \frac{{x}^{2}}{{σ}^{2}}$$

The parameters depth (D) and width (W) of the pattern as depicted in FIG. 3A can be obtained from the aforementioned equations. The depth of the pattern along the z-axis (x=0) can be expressed as:

$$D = A = \frac{{γH}_{o}}{1 + \frac{γ {H}_{o}}{β}} ln \frac{{E}_{p}}{{E}_{t h}}$$

The top width (W) can be obtained by putting z=0 into the aforementioned equation.

$$W = 2 {x}_{o} = 2 \sqrt{A / B} = 2 \sqrt{2 σ} \sqrt{ln \frac{{E}_{p}}{{E}_{t h}}}$$

where, xₒ is the half of the top width at z=0 of the quadratic equation obtained. Therefore, the following quadratic profile can be used to fit the line profiles obtained and extract parameters like D and W for each pattern.

$$z = - D + \{ \frac{4 D}{{W}^{2}} \} {x}^{2}$$

FIG. 12B depicts a representative plot of E(x, z) vs x over the thickness (z) of the polymer film. The Gaussian laser intensity pattern yields a parabolic etch shape because the wings of the Gaussian do not exceed the Eₜₕ needed to start dissolution. If E>Eₜₕ, the polymer can dissolve in the solvent. If E<Eₜₕ, the polymer may not dissolve in the solvent. This relationship was represented in the Gaussian spectra in FIGS. 12B and 12C. FIG. 12C is a perspective view of FIG. 3B expanded in the z-direction. Depicted in FIG. 12C, wherever the Eₜₕ plane cuts the Gaussian spectrum, the line profile of the pattern can be obtained. The parabolic etch shape is the intersection of the Eₜₕ plane with the Gaussians, corresponding to cases where dissolution occurs. Examples of the line profiles can be seen in FIG. 11.

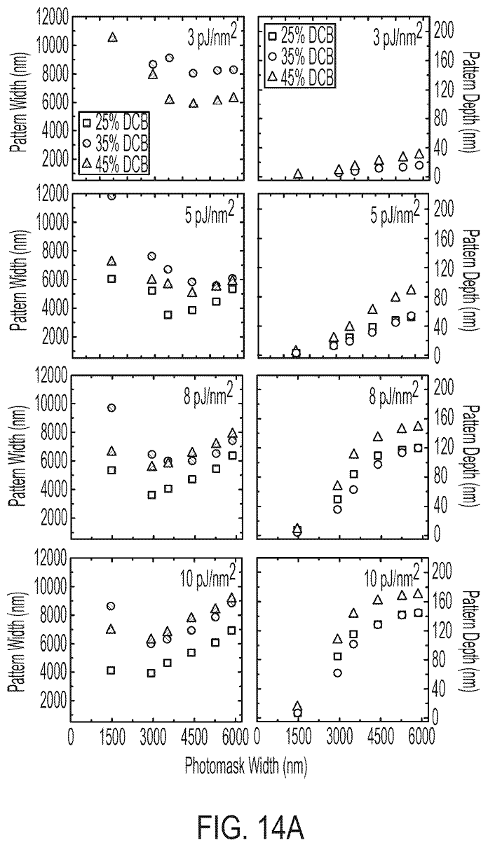

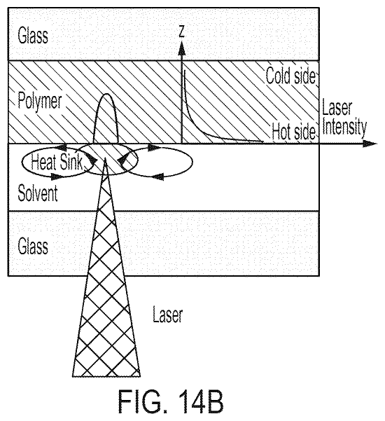

The quadratic model was used to fit all the obtained patterns and extract parameters such as pattern width (W) and pattern depth (D). FIGS. 13A and 13B depict the photomask width vs pattern width and depth for the “thru glass” orientation for P3HT at 3, 5, 8, and 10 pJ/nm² as well as a schematic of the dissolution and temperature gradients in the experiment polymer film 902 for the “thru glass” orientation. FIGS. 14A and 14B depict the photomask width vs pattern width and depth for the “thru solvent” orientation for P3HT at 3, 5, 8, and 10 pJ/nm² as well as a schematic of the dissolution and temperature gradients in the experiment polymer film 902 for the “thru solvent” orientation. Differences between the W and D vs exposure intensity for the 2 orientations can be due to different in thermal transport out of the polymer film.

Heat transfer in the polymer film can determine and/or be used to control variation of W and D with the photomask width for the two solvent orientations. Thermal transport can be modeled based on assumptions such as (1) glass being transparent at 375 nm and the polymer film being the only optically absorbing material in the system, (2) that light absorbs with exponential reduction in intensity with depth, the heat gradient must match the optical field intensity E(x, z), and (3) the glass-polymer interface is hotter than the solvent-polymer interface in the “thru glass” orientation and the solvent-polymer interface is hotter than the glass-polymer interface in the “thru solvent” orientation.

For P3HT, 25% DCB does not result in any patterns at 3 pJ/nm² fluence. This can be understood as at 3 pJ/nm² fluence, a temperature of P3HT was lower than 108 °C. For the “thru glass” orientation, pattern width increases linearly with the photomask width for all fluences while D saturates at approximately 220 nm which is the layer thickness as seen in FIG. 14A. The laser hits the polymer at the polymer-glass interface as seen in FIG. 14B. While P3HT is a poor conductor of heat (k=0.158 W/mK), glass acts as a heat sink (k~=1.1 W/mK) and pulls heat away from the polymer film. As a result, the glass heats laterally and results in W that is wider than the photomask width as depicted in FIG. 13A. The polymer film layer closer to the glass heats up first. Heat diffuses slowly to the cold side which is the polymer-solvent interface but more quickly to the glass heat sink. Dissolution into the solvent must occur at the polymer-solvent interface. Since the glass heat sink is closer to the hot polymer interface in this case, vertical heat transfer in the z-direction is more efficient than lateral heat transfer in the x-direction, which results in lower W and higher D as compared to the “thru solvent”.

For the “thru glass” orientation, the 80 nm layer of the solvent closer to the glass gets heated first (B=~80 nm) and the heat diffuses to the cold side of the solvent (e.g., further from the first heated glass) which is closer to the polymer-solvent interface. The dissolution process always occurs at the polymer-solvent interface. Since the heat sink is closer to the hot polymer in this orientation, vertical heat transfer (in z-direction) is stronger than lateral heat transfer (in x-direction) which results in lower pattern widths and higher pattern depths.

In the “thru solvent” orientation photomask width vs pattern width and depth depicted in FIG. 13A; the lower photomask widths resulted in a higher W. W decreases first until a “certain photomask width” and then increases again. This dip in W decreases with increasing fluence and it eventually approaches linearity similar to the “thru glass” orientation. D is larger in the “thru glass” orientation compared to the “thru solvent” orientation. The pattern depth increases linearly with photomask width up till 5 pJ/nm² fluence as seen in FIG. 14A and then begins to saturate (e.g., curve) for higher fluences at higher photomask widths. Patterns are deeper in the “thru glass” orientation which could be due to a difference in ion heat transfer mechanisms (e.g., how heat is transferred) between the two orientations. The differences in ion heat transfer mechanisms can be seen in FIGS. 13B and 14B. The laser makes first contact with the polymer at the polymer-solvent interface for the “thru solvent” orientation depicted in FIG. 13B. For this orientation, a hot side of the polymer is closer to the solvent. For this orientation, the solvent serves two purposes rather than one purpose in the “thru glass” orientation (e.g., a heat sink). The solvent convects in response to thermal gradients, resulting in a more significant lateral heat spread through the solvent compared to the “thru glass” case. Solvent convection, which is not considered in the model, is likely the reason for higher W and lower D obtained in the “thru solvent” orientation. For a future scale-up of photothermal patterning, a solvent flow would enable control of heat transport through the solvent layer.

Dimensionless variables can be used to reduce a number of variables and apply the quadratic model to other systems (e.g. photolithography systems, other orientations). Dimensionless variables

$${z}^{*} = \frac{z}{A}$$

and

$${x}^{*} = \frac{x}{\sqrt{\frac{A}{B}}}$$

can be used. The

Dimensionless variables were chosen to predict the W and D of a photothermally etched feature in polymer films using only information like Eₜₕ, DTₛₜₐᵣₜ, DT_{end}, E_{P}, and time. The dimensionless variables can be input into

$$z = - D + \{ \frac{4 D}{{W}^{2}} \} {x}^{2} to obtain :$$

$${z}^{*} = -- 1 + {x}^{* 2} .$$

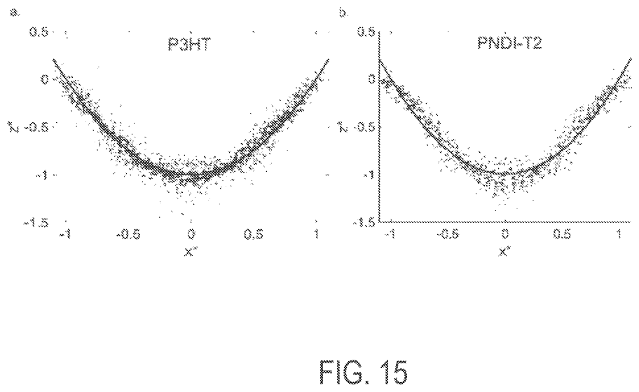

Applying the dimensionless model to all the tested patterns, master curves can be obtained as depicted in FIG. 15. FIG. 15 depicts master curves for P3HT and PNDI-T2 that shows data collapse across the entire range of operating conditions. The master curve collapses all data to a narrow range of values across the entire range of operating conditions. The master curve is representative of the fact that any semiconducting polymer can be patterned with a combination of good solvents and the right laser wavelength. The two master curves are not identical which indicates that PNDI-T2 cannot be patterned under the same conditions as P3HT. The collapse of the data into one curve demonstrates that all data under all conditions can be accurately described by the model for a particular polymer and that the model should be trusted to have predictive power outside the measured range, for example, for the same polymer in a different solvent mixture.

### EQUIVALENTS

It is to be understood that while the disclosure has been described in conjunction with the above embodiments, that the foregoing description and examples are intended to illustrate and not limit the scope of the disclosure. Other aspects, advantages, and modifications within the scope of the disclosure will be apparent to those skilled in the art to which the disclosure pertains.

Unless otherwise defined, all technical and scientific terms used herein have the same meaning as commonly understood by one of ordinary skill in the art to which this disclosure belongs. All nucleotide sequences provided herein are presented in the 5′ to 3′ direction.

The embodiments illustratively described herein may suitably be practiced in the absence of any element or elements, limitation or limitations, not specifically disclosed herein. Thus, for example, the terms “comprising,” “including,” containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the disclosure.

Thus, it should be understood that although the present disclosure has been specifically disclosed by specific embodiments and optional features, modification, improvement and variation of the embodiments therein herein disclosed may be resorted to by those skilled in the art, and that such modifications, improvements and variations are considered to be within the scope of this disclosure. The materials, methods, and examples provided here are representative of particular embodiments, are exemplary, and are not intended as limitations on the scope of the disclosure.

The scope of the disclosure has been described broadly and generically herein. Each of the narrower species and subgeneric groupings falling within the generic disclosure also form part of the disclosure. This includes the generic description with a proviso or negative limitation removing any subject matter from the genus, regardless of whether or not the excised material is specifically recited herein.

In addition, where features or aspects of the disclosure are described in terms of Markush groups, those skilled in the art will recognize that embodiments of the disclosure may also thereby be described in terms of any individual member or subgroup of members of the Markush group.

All or part of the systems, devices, components, and processes described herein and their various modifications (hereinafter referred to as “the processes”) can be implemented, at least in part, via one or more computing devices and/or computer program products, i.e., a computer program tangibly embodied in one or more tangible, physical hardware storage devices that are computer and/or machine-readable storage devices for execution by, or to control the operation of, data processing apparatus, e.g., a programmable processor, a computer, or multiple computers. A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a network. Various systems can be implemented in a distributed computing environment, cloud computing environment, client-server environment, data center environment, virtual computing environment, or various combinations thereof. Various systems can include one or more central processing units (CPUs), graphics processing units (GPUs), or combinations thereof, to perform operations described herein, including in parallel or multi-thread computing operations. Various systems can be implemented using portable electronic devices, such as smartphones, wearable devices, head up displays (HUDs), or combinations thereof, including in artificial reality, augmented reality, or virtual reality implementations.

Various systems can include or be coupled with user interface components for presenting information using audio output devices and/or display devices, and for receiving input using input devices including but not limited to image capture devices, microphones, keyboards, or mice. User interfaces can include interfaces to process information such as voice, speech, gesture, or movements of a user to determine user inputs according to the processed information.

Wired and wireless network communication interfaces can be used to facilitate communication amongst various devices and systems. This can include, for example, components to enable communication using various communication networks and protocols, including but not limited to cellular, Bluetooth, Wi-Fi, Ethernet, near field communication (NFC), local area networks (LANs), wide area networks (WANs), or other networks.

Processes described herein can be implemented by systems for performing training, updating, inference generation, runtime operation, or various other operations for machine learning models or artificial intelligence systems. Training can be performed using various combinations of datasets, including federated or decentralized datasets. Training operations can include supervised or unsupervised learning operations. Models can be stored, maintained, or communicated between systems and devices as data structures representing structures of the models, such as arrangements of layers of network models, or as a subset of features of the models, such as weights, biases, parameters, hyper-parameters, or various combinations thereof.

Processors suitable for the execution of a computer program include, by way of example, both general and special purpose microprocessors, and any one or more processors of any kind of digital computer, including but not limited to application-specific integrated circuits (ASICs) or field programmable gate arrays (FPGAs). Generally, a processor will receive instructions and data from a read-only storage area or a random-access storage area or both. Elements of a computer (including a server) include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, e.g., magnetic, magneto-optical disks, or optical disks. Applications implemented by systems described herein can operate using application programming interfaces (APIs), which may expose particular functions responsive to requests, such as to communicate data across devices in various computing environments.

Computer program products are stored in a tangible form on non-transitory computer readable media and non-transitory physical hardware storage devices that are suitable for embodying computer program instructions and data. These include all forms of non-volatile storage, including by way of example, semiconductor storage area devices, e.g., EPROM, EEPROM, and flash storage area devices; magnetic disks, e.g., internal hard disks or removable disks; magneto-optical disks; and CD-ROM and DVD-ROM disks and volatile computer memory, e.g., RAM such as static and dynamic RAM, as well as erasable memory, e.g., flash memory and other non-transitory devices.

The construction and arrangement of the systems and methods as shown in the various embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced. Other substitutions, modifications, changes, and omissions may be made in the design, operating conditions and arrangement of embodiments without departing from the scope of the present disclosure.

All publications, patent applications, patents, and other references mentioned herein are expressly incorporated by reference in their entirety, to the same extent as if each were incorporated by reference individually. In case of conflict, the present specification, including definitions, will control.

1. A system for photothermal patterning comprising:
a flow cell comprising:
a cover plate;
a substrate having a surface arranged at a distance from the cover plate to form a cavity between the surface and the cover plate;
a polymer layer on the surface;
an inlet port coupled with the cavity;
an outlet port coupled with the cavity;
a liquid pump coupled with the inlet port, the liquid pump configured to flow a solvent through the inlet port and the cavity and out of the outlet port; and
an optical source configured to direct electromagnetic radiation onto a portion of the polymer layer.

2. The system of claim 1, wherein:
the optical source is configured to cause local heating in the portion of the polymer layer, thereby causing the portion of the polymer layer to dissolve in the solvent; and
the liquid pump is configured to flow the solvent through the cavity to sweep dissolved polymer out of the cavity.

3. The system of claim 1, wherein the distance is a fixed distance between about 0.1 mm and about 0.6 mm.

4. The system of claim 1, wherein the liquid pump is at least one of a syringe pump, a recirculating pump, or a metered pump.

5. The system of claim 1, wherein the substrate has a circular shape.

6. The system of claim 1, wherein the substrate has a rectangular shape.

7. The system of claim 1, wherein the optical source comprises a laser; and
the system further comprises a positioning component to move the optical source laterally with respect to the substrate or to move the substrate laterally with respect to the optical source.

8. The system of claim 1, wherein the optical source comprises a lamp and a shadow mask.

9. The system of claim 1, wherein the polymer layer comprises poly(3-hexylthiophene) (P3HT); poly(9,9-dioctylfluorene-alt-benzothiadiazole) (F8BT); poly(3-butylthiophene-2,5-diyl) (P3BT); poly[2,5-bis(2-octyldodecyl) pyrrolo[3,4-c]pyrrole-1,4 (2H,5H)-dione-3,6-diyl)-alt-(2,2′; 5′,2″; 5″,2″″-quaterthiophen-5,5′″-diyl) (pDPP-4T); poly {2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl} (pDPP-3T); poly[2,5-(2-octyldodecyl)-3,6-diketopyrrolopyrrole-alt-5,5-(2,5-di(thien-2-yl) thieno[3,2-b]thiophene)] (pDPP-2T); or a mixture thereof.

10. The system of claim 1, wherein the system further comprises the solvent disposed in the cavity.

11. The system of claim 10, wherein the solvent comprises a mixture of dichlorobenzene and cyclohexanone.

12. A method of photothermal patterning a polymer film, the method comprising:
depositing the polymer layer on a surface of a substrate;
flowing a solvent over the polymer layer; and
while flowing, exposing a portion of the polymer layer to electromagnetic radiation to solubilize the portion of the polymer layer and sweep solubilized organic polymer from the surface in the flowing solvent.

13. The method of claim 12, wherein flowing the solvent comprises flowing the solvent at a fixed rate.

14. The method of claim 12, wherein flowing the solvent comprises flowing the solvent with a pulsed variable rate.

15. The method of claim 12, wherein flowing the solvent comprises flowing the solvent at a fixed depth of solvent on the polymer layer of about 0.1 mm to about 1 mm.

16. The method of claim 12, wherein the polymer layer comprises poly(3-hexylthiophene) (P3HT); poly(9,9-dioctylfluorene-alt-benzothiadiazole) (F8BT); poly(3-butylthiophene-2,5-diyl) (P3BT); poly[2,5-bis(2-octyldodecyl) pyrrolo[3,4-c]pyrrole-1,4 (2H,5H)-dione-3,6-diyl)-alt-(2,2′; 5′,2″; 5″,2″″-quaterthiophen-5,5′″-diyl) (pDPP-4T); poly {2,2′-[(2,5-bis(2-hexyldecyl)-3,6-dioxo-2,3,5,6-tetrahydropyrrolo[3,4-c]pyrrole-1,4-diyl)dithiophene]-5,5′-diyl-alt-thiophen-2,5-diyl} (pDPP-3T); poly[2,5-(2-octyldodecyl)-3,6-diketopyrrolopyrrole-alt-5,5-(2,5-di(thien-2-yl) thieno[3,2-b]thiophene)] (pDPP-2T); or a mixture thereof.

17. The method of claim 12, wherein the solvent comprises a mixture of dichlorobenzene and cyclohexanone.

18. A flow cell for photothermal patterning comprising:
a support;
a substrate coupled to the support via mechanical coupling or a pressure differential induced by a vacuum;
a cover plate coupled to the support via adhesive or a pressure differential induced by a vacuum, the cover plate positioned parallel to the substrate and at a fixed distance from the substrate to create a cavity therebetween, the fixed distance being about 0.3 mm to about 0.6 mm;
an inlet port configured to direct a solvent into the cavity; and
an outlet port configured to direct the solvent out of the cavity.

19. The flow cell of claim 18, further comprising a polymer layer on the substrate.

20. The flow cell of claim 18, further comprising at least one pump coupled with the inlet port.
